(19) United States
(12) Patent Application Publication
(10) Pub. No.: US 2007/0194419 A1
(43) Pub. Date: Aug. 23, 2007

(54) Semiconductor module and method of manufacturing the same

(75) Inventor: Takashi Ozawa, Nagano (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: SHINKO ELECTRIC INDUSTRIES CO. LTD., Nagano-shi (JP)

(21) Appl. No.: 11/709,137

(22) Filed: Feb. 22, 2007

(30) Foreign Application Priority Data
Feb. 23, 2006 (JP) 2006-046398

(51) Int. Cl. H01L 23/02

(52) U.S. Cl. 257/678

(57) ABSTRACT

A semiconductor module of the present invention includes a wiring substrate having a wiring layer, a passive component mounted to be connected to the wiring layer in a center major portion of the wiring substrate, a resin portion formed selectively in an area except the wiring layer on a peripheral side of the wiring substrate to seal the passive component, and a semiconductor chip mounted on the resin portion and connected to the wiring layer on the peripheral side of the wiring substrate via a wire.

### CROSS-REFERENCE TO RELATED APPLICATIONS

This application is based on and claims priority of Japanese Patent Application No. 2006-046398 filed on Feb. 23, 2006, the entire contents of which are incorporated herein by reference.

### BACKGROUND OF THE INVENTION

1. Field of the Invention

The present invention relates to a semiconductor module and a method of manufacturing the same and, more particularly, a semiconductor module constructed by mounting a semiconductor chip, a passive component, and the like on a wiring substrate and a method of manufacturing the same.

2. Description of the Related Art

There is the semiconductor module constructed by mounting the semiconductor chip and the passive component on the wiring substrate in the prior art. As shown in FIG. 1, in the semiconductor module in the prior art, a semiconductor chip 200 is adhered onto a center portion of a wiring substrate 100 having wiring layers 110 and external connection terminals 120 by an adhesive 220, and a passive component 300 such as a capacitor, a resistor, or the like is mounted to be connected to the wiring layers 110 of the wiring substrate 100 on the side of the semiconductor chip 200 respectively. The semiconductor chip 200 is face-up mounted to direct its connection pads upward, and connection pads are electrically connected to the wiring layers 110 of the wiring substrate 100 via wires 240. Also, the semiconductor chip 200 and the passive components 300 are sealed with a sealing resin 400.

In Patent Literature 1 (Patent Application Publication (KOKAI) Hei 5-343608), the hybrid integrated circuit device having such a structure that the subassembly in which the passive components and the active devices are arranged in the lateral direction and built therein is mounted on a surface of the wiring substrate as the mother board and the external terminals of the subassembly are connected to the conductor layers on the wiring substrate by the wire bonding is set forth.

Also, in Patent Literature 2 (Patent Application Publication (KOKAI) 2004-214249), the semiconductor module having such a structure that the lower semiconductor chip is mounted on the bottom of the recess on the upper surface of the module substrate, the upper semiconductor chip is stacked on the upper surface of the supporting body made of the conductor provided to the periphery of the recess, and the passive components are mounted on the module substrate on the side of the semiconductor chip is set forth.

As described above, in the semiconductor module (FIG. 1) in the prior art, the semiconductor chip 200 and the passive components 300 are mounted on the wiring substrate 100 two-dimensionally in a state aligned horizontally. At this time, in order to ensure the reliability upon printing the solder to mount the passive components 300 or bonding the semiconductor chip 200 by the wire bonding, a space (an area R in FIG. 1) must be provided to some extent between the semiconductor chip 200 and the passive components 300.

In this manner, in the wiring substrate 100 of the semiconductor module in the prior art, the area on which the passive component 300 is mounted must be secured separately at some interval to the area on which the semiconductor chip 200 is mounted besides the area. Therefore, since the wiring substrate having a relatively large area is needed, there exists the problem that it cannot easily cope with a miniaturization of the semiconductor module.

Also, in Patent Literature 2, the semiconductor chips are stacked and mounted three-dimensionally, nevertheless it is also hard to miniaturize the semiconductor module since the passive components are mounted in the lateral direction of the semiconductor chip.

### SUMMARY OF THE INVENTION

It is an object of the present invention to provide a semiconductor module having a structure capable of coping easily with a miniaturization, in the semiconductor module constructed by mounting the semiconductor chip and the passive component on the wiring substrate, and a method of manufacturing the same.

A semiconductor module of the present invention, includes a wiring substrate having a wiring layer; a passive component mounted to be connected to the wiring layer in a center major portion of the wiring substrate and; a resin portion formed selectively in an area except the wiring layer on a peripheral side of the wiring substrate to seal the passive component; and a semiconductor chip mounted on the resin portion and connected to the wiring LAYER on the peripheral side of the wiring substrate via a wire.

In the semiconductor module of the present invention, the passive component (the capacitor, the resistor, or the like) is connected and mounted onto the wiring layer in the center major portion of the wiring substrate, and the passive component is sealed with the resin by forming selectively the resin portion in the mounting area of the passive component except the wiring layer on the peripheral side of the wiring substrate. Also, the semiconductor chip (the active device such as the LSI chip, the CMOS image sensor, or the like) is mounted on the resin portion, and the semiconductor chip is connected to the wiring layer on the peripheral side of the wiring substrate via the wire.

In the present invention, the passive component and the semiconductor chip are stacked three-dimensionally and mounted on the wiring substrate, and the lower area of the semiconductor chip is utilized effectively as the mounting area of the passive component. Therefore, a miniaturization of the semiconductor module can be achieved rather than the prior art.

Also, a semiconductor module manufacturing method of the present invention includes the steps of connecting and mounting a passive component to a wiring layer in a center major portion of the wiring substrate; forming selectively a resin portion, which seals the passive component, in an area except the wiring layer on a peripheral side of the wiring substrate; and adhering a semiconductor chip onto the resin layer, and connecting and mounting the semiconductor chip onto the wiring layer exposed from the peripheral side of the wiring substrate via a wire.

The semiconductor module having the above constitutions can be easily manufactured by suing the manufacturing method of the present invention. In the present invention, the resin portion for sealing the passive component is formed partially to expose the wiring layer on the peripheral side of the wiring substrate. Therefore, upon stacking and mounting the semiconductor chip over the passive component, the semiconductor chip can be connected easily to the wiring layer exposed on the peripheral side of the wiring substrate by the wire. As a result, the miniaturized semiconductor module in which the passive component and the semiconductor chip are stacked three-dimensionally on the wiring substrate can be manufactured easily not to add the particular steps.

As described above, according to the present invention, a miniaturization of the semiconductor module constructed by mounting the passive component and the semiconductor chip on the wiring substrate can be achieved.

### BRIEF DESCRIPTION OF THE DRAWINGS

FIG. 1 is a sectional view showing a semiconductor module in the prior art;

FIGS. 2A to 2E are sectional views showing a semiconductor module manufacturing method according to a first embodiment of the present invention;

FIG. 3 is a sectional view showing a semiconductor module according to the first embodiment of the present invention;

FIG. 4 is a sectional view showing a semiconductor module according to a variation of the first embodiment of the present invention;

FIGS. 5A to 5D are sectional views showing a semiconductor module manufacturing method according to a second embodiment of the present invention;

FIG. 6 is a sectional view showing a semiconductor module according to the second embodiment of the present invention; and

FIG. 7 is a sectional view showing a semiconductor module according to a variation of the second embodiment of the present invention.

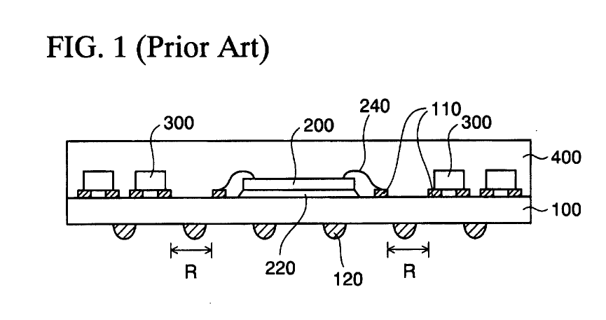

### DETAILED DESCRIPTION OF THE PREFERRED EMBODIMENTS

Embodiments of the present invention will be explained with reference to the accompanying drawings hereinafter.

### First Embodiment

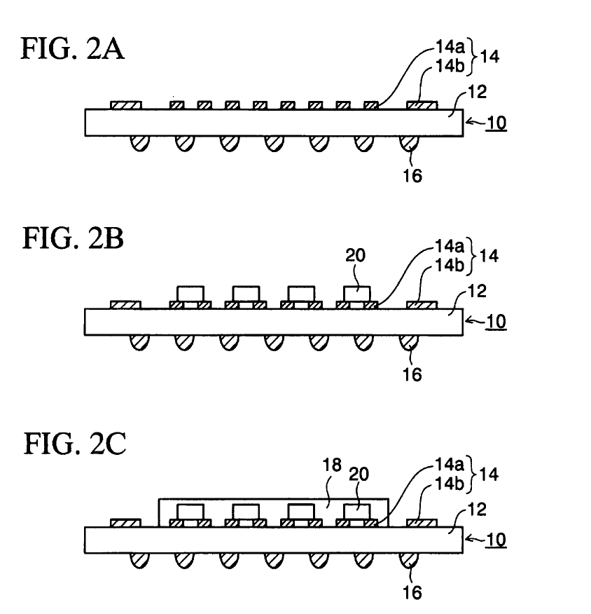

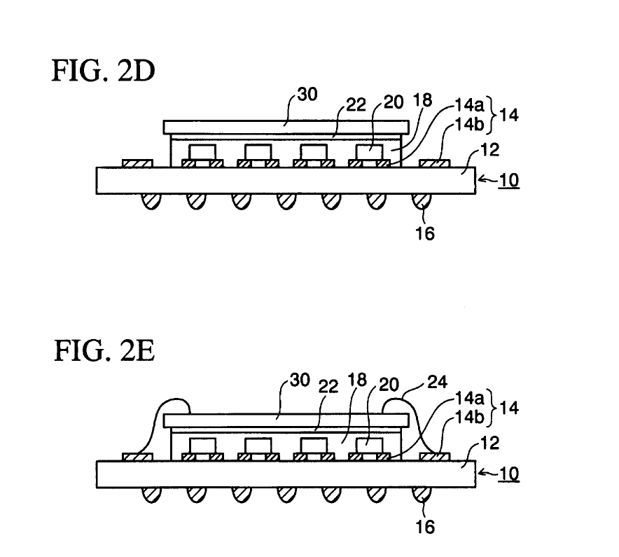

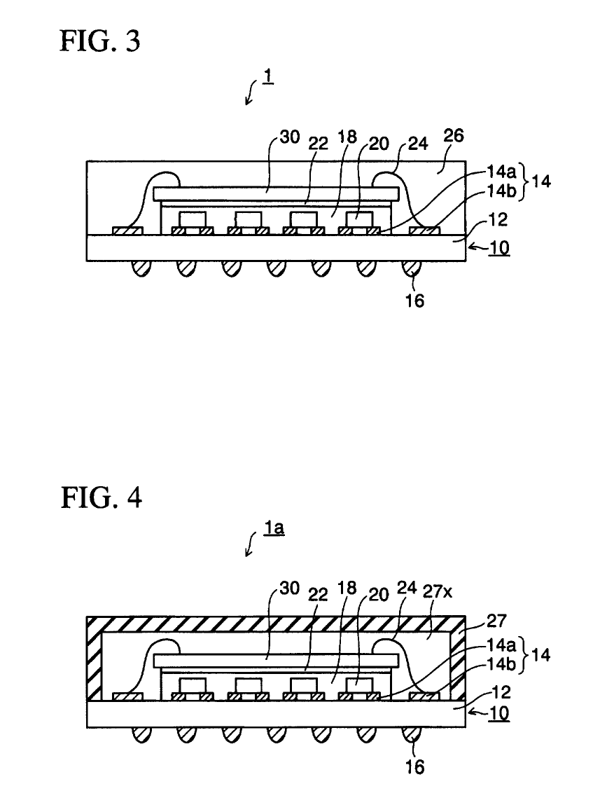

FIGS. 2A to 2E are sectional views showing a semiconductor module manufacturing method according to a first embodiment of the present invention, and FIG. 3 and FIG. 4 are sectional views showing a semiconductor module according to the first embodiment of the present invention.

In the semiconductor module manufacturing method of the present embodiment, first, a wiring substrate 10 shown in FIG. 2A is prepared. In the wiring substrate 10 in FIG. 2A, a substrate 12 made of insulating material, or the like, wiring layers 14 formed on an upper surface of this substrate, and external connection terminals 16 provided on a lower surface of this substrate are shown. The wiring layers 14 are connected electrically to the external connection terminals 16 via through holes (not shown) provided in the substrate 12. As the wiring substrate 10, various substrates such as a flexible substrate, a rigid substrate, and the like can be employed. Normally the wiring substrate 10 is constructed by building a plurality of stacked wiring layers in the substrate 12. The wiring layer 14 exposed from the wiring substrate 10 is constructed by first wiring layers 14a provided for the passive component in a center major portion of the mounting area, and a second wiring layer 14b provided for the semiconductor chip on the peripheral side of the mounting area.

Then, as shown in FIG. 2B, electrodes of passive components 20 are electrically connected and mounted onto the first wiring layers 14a in the center major portion of the wiring substrate 10 via the solder, or the like. As the passive component 20, the capacitor component, the resistor component, or the like is used. An example in which the passive components 20 are connected to the first wiring layers 14a respectively to arrange respective electrodes exposed from both end sides of the passive components in the horizontal direction is shown in FIG. 2B.

Then, as shown in FIG. 2C, a resin portion 18 for sealing the passive components 20 is formed by forming selectively the resin material on the area of the wiring substrate 10 in which the passive components 20 are mounted. At this time, the resin portion 18 is formed in the area except the second wiring layers 14b on the peripheral side of the wiring substrate 10, and the second wiring layers 14b are kept in the exposed state.

As the method of forming the resin portion 18, the die having the cavity corresponding to the resin forming area may be placed on the wiring substrate 10, and then the melted resin material such as an epoxy resin, or the like may be poured into the die. Also, the liquid resin may be coated selectively on the resin forming area, and then such resin may be shaped by using the die.

Then, as shown in FIG. 2D, a semiconductor chip 30 is adhered onto the resin portion 18 by an adhesive 22 such that connection pads (not shown) of the semiconductor chip 30 are directed upward (face up). Here, an area of the resin portion 18 is adjusted to respond to a size of the semiconductor chip 30 to an extent in which the semiconductor chip 30 can be stably mounted.

The semiconductor chip 30 is the active component such as various LSI chips obtained by fabricating the transistors, etc. in the semiconductor substrate (silicon substrate). Alternately, the imaging device such as the CMOS image sensor, or the like or the MEMS (Micro Electro Mechanical Systems) device may be used as the semiconductor chip, as explained later in the variation.

Then, as shown in FIG. 2E, the connection pads of the semiconductor chip 30 are connected electrically to the second wiring layers 14b exposed on the periphery side of the wiring substrate 10 with wiring 24 by the wire bonding method. Thus, the passive components 20 and the semiconductor chip 30 are stacked three-dimensionally and mounted on the wiring substrate 10.

In this manner, in the present embodiment, the semiconductor chip 30 is stacked three-dimensionally and mounted on the area in which the passive components 20 are mounted. Therefore, unlike the case where the semiconductor chip and the passive components are mounted two-dimensionally in the prior art, there is no need to keep the mounting areas of the semiconductor chip 30 and the passive components 20 separately on the wiring substrate 10, and thus an area of the wiring substrate 10 can be reduced rather than the prior art.

Then, as shown in FIG. 3, a sealing resin 26 for sealing the semiconductor chip 30, the wires 24, and the second wiring layers 14b to which the wires 24 are connected is formed.

With the above, a semiconductor module 1 according to the first embodiment is obtained.

In this case, the passive components 20 and the semiconductor chip 30 may be stacked and mounted on respective mounting areas of the wiring substrate 10 in which a plurality of mounting areas are defined, and then the wiring substrate 10 may be divided into individual semiconductor modules 1.

In the semiconductor module 1 according to the present embodiment, as shown in FIG. 3, the passive components 20 are connected to the first wiring layers 14a in the center major portion of the wiring substrate 10 and mounted thereon, and the passive components 20 are sealed with the resin by forming selectively the resin portion 18 on the area in which the passive components 20 are mounted. The semiconductor chip 30 is adhered onto the resin portion 18 by the adhesive 22, and the connection pads of the semiconductor chip 30 are electrically connected to the second wiring layers 14b on the peripheral side of the wiring substrate 10 by the wires 24. Then, the semiconductor chip 30, the wires 24, and the second wiring layers 14b to which the wires 24 are connected are sealed with the sealing resin 26.

According to the semiconductor module 1 of the present embodiment, the lower area of the semiconductor chip 30 is utilized effectively as the mounting area for the passive components 20 by stacking the passive components 20 and the semiconductor chip 30 three-dimensionally on the wiring substrate 10 to mount. Therefore, a miniaturization of the semiconductor module can be achieved much more than the prior art.

Also, the resin portion 18 for sealing the passive components 20 is formed partially to expose the second wiring layers 14b provided for the semiconductor chip 30. Therefore, upon stacking the semiconductor chip 30 over the passive components 20 to mount, the semiconductor chip 30 can be electrically connected easily to the second wiring layers 14b on the wiring substrate 10 by the wires 24. As a result, the miniaturized semiconductor module 1 in which the passive components 20 and the semiconductor chip 30 are stacked three-dimensionally on the wiring substrate 10 can be manufactured easily not to add the particular steps.

A semiconductor module 1a according to a variation of the present embodiment is shown in FIG. 4. In the semiconductor module 1a according to the variation, the imaging device such as the CMOS image sensor, or the like, or the MEMS device such as the switch device, the acceleration sensor, or the like is mounted as the semiconductor chip 30. Then, instead of the sealing of the sealing resin 26, a cap 27 having a cavity 27x therein and made of a transparent glass, or the like is provided on the wiring substrate 10. Thus, the semiconductor chip 30 (the imaging device, or the like) is housed in the cavity 27x of the cap 27 and is hermetically sealed.

In FIG. 4, remaining elements are similar to those in FIG. 3. Therefore, their explanation will be omitted herein by affixing the same reference symbols to these elements. The semiconductor module 1a of the variation can achieve the similar advantages to the semiconductor module 1 in FIG. 3.

### Second Embodiment

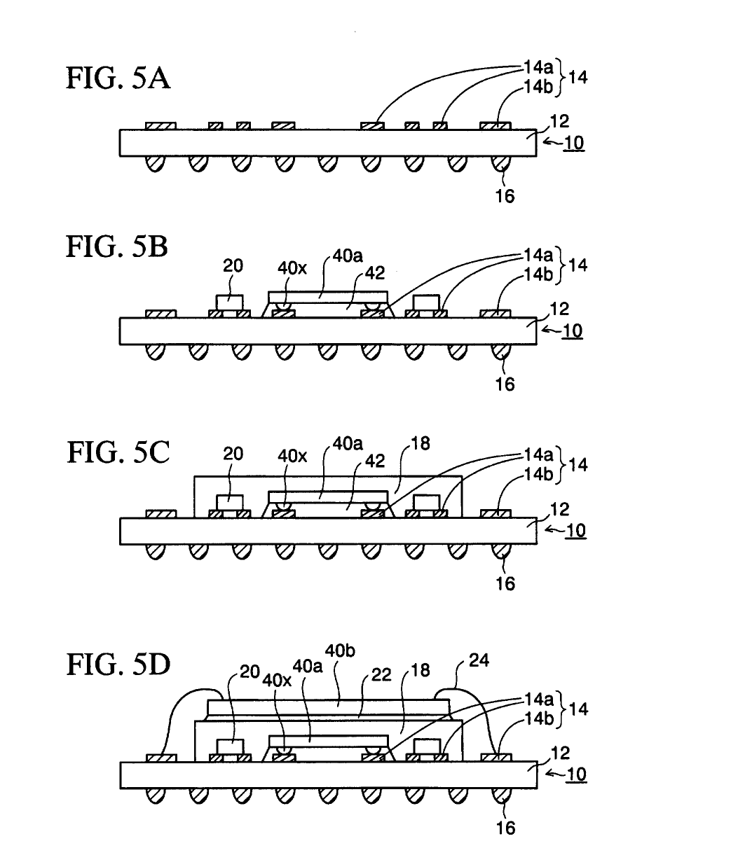

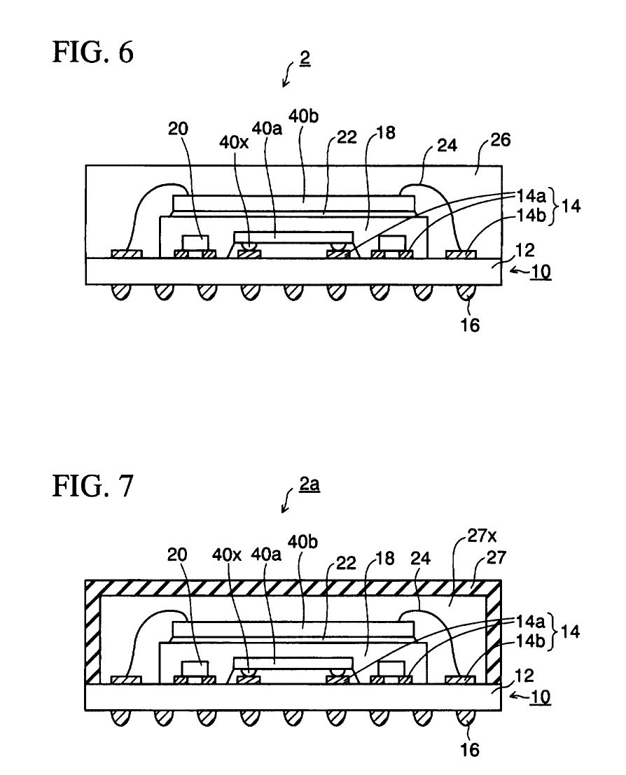

FIGS. 5A to 5D are sectional views showing a semiconductor module manufacturing method according to a second embodiment of the present invention, and FIG. 6 and FIG. 7 are sectional views showing a semiconductor module according to the second embodiment of the present invention.

As shown in FIG. 5A, first, the same wiring substrate 10 as the first embodiment is prepared. Then, as shown in FIG. 5B, a lower semiconductor chip 40a having bumps 40x thereon is prepared, and the lower semiconductor chip 40a is mounted by flip-chip connecting the bumps 40x to the first wiring layers 14a on the wiring substrate 10. Then, an underfill resin 42 is filled in a clearance between the lower semiconductor chip 40a and the wiring substrate 10. Then, the passive components 20 similar to the first embodiment are connected to the first wiring layers 14a on the outer peripheral portion of the lower semiconductor chip 40a and are mounted thereon. In this manner, in the present embodiment, the first wiring layers 14a in the center major portion of the wiring substrate 10 act as the wiring layers used to connect the lower semiconductor chip 40a and the passive components 20.

At this time, the lower semiconductor chip 40a is flip-chip connected. Therefore, the passive components 20 can be mounted with good reliability in the position relatively close to the lower semiconductor chip 40a not to leave an extra space, unlike the case where the semiconductor chip is connected by the wires.

Then, as shown in FIG. 5C, the resin portion 18 same as the first embodiment is formed selectively in the area in which the lower semiconductor chip 40a and the passive components 20 are mounted. Thus, the lower semiconductor chip 40a and the passive components 20 are sealed with the resin.

Then, as shown in FIG. 5D, like the first embodiment, an upper semiconductor chip 40b is face-up adhered onto the resin portion 18 by the adhesive 22. Then, connection pads of the upper semiconductor chip 40b are connected electrically to the second wiring layers 14b exposed on the peripheral side of the wiring substrate 10 by the wires 24.

Then, as shown in FIG. 6, the sealing resin 26 for sealing the upper semiconductor chip 40b, the wires 24, and the second wiring layers 14b to which the wires 24 are connected is formed.

With the above, a semiconductor module 2 according to the second embodiment is obtained.

In the semiconductor module 2 of the second embodiment, as shown in FIG. 6, the lower semiconductor chip 40a and the passive components 20 are connected electrically to the first wiring layers 14a in the center major portion of the wiring substrate 10 in a state that the lower semiconductor chip 40a and the passive components 20 are aligned two-dimensionally in the horizontal direction. Then, the resin portion 18 is formed selectively in the area on which the lower semiconductor chip 40a and the passive components 20 are mounted, and thus the lower semiconductor chip 40a and the passive components 20 are sealed with the resin portion 18. Then, the upper semiconductor chip 40b is adhered onto the resin portion 18 by the adhesive 22 in a state that the connection pads are directed upward (face-up). Then, the connection pads of the upper semiconductor chip 40b are connected electrically to the second wiring layers 14b on the peripheral side of the wiring substrate 10 by the wires 24. Then, the upper semiconductor chip 40b, the wires 24, and the second wiring layers 14b to which the wires 24 are connected are sealed with the sealing resin 26.

The semiconductor module 2 of the second embodiment can achieve the similar advantages to the semiconductor module 1 of the first embodiment. In addition, the lower area of the upper semiconductor chip 40b is utilized effectively as not only the amounting area of the passive components 20 but also the amounting area of the lower semiconductor chip 40a. Therefore, a margin of design can be widened, and thus the semiconductor module of a higher density can be miniaturized in structure.

A semiconductor module 2a according to a variation of the second embodiment is shown in FIG. 7. In the semiconductor module 2a of the variation of the second embodiment, like the variation of the first embodiment, the upper semiconductor chip 40b is formed of the imaging device, the MEMS device, or the like. Then, the cap 27 having the cavity 27x therein is provided on the wiring substrate 10, and the upper semiconductor chip 40b (the imaging device, or the like) is housed into the cavity 27x of the cap 27 and is hermetically sealed.

What is claimed is:

1. A semiconductor module, comprising:
a wiring substrate having a wiring layer;
a passive component mounted to be connected to the wiring layer in a center major portion of the wiring substrate;
a resin portion formed selectively in an area except the wiring layer on a peripheral side of the wiring substrate to seal the passive component; and
a semiconductor chip mounted on the resin portion and connected to the wiring layer on the peripheral side of the wiring substrate via a wire.

2. A semiconductor module according to claim 1, further comprising:
a sealing resin for sealing the semiconductor chip, the wire, and the wiring layer to which the wire is connected.

3. A semiconductor module according to claim 1, wherein a cap having a cavity is provided to the wiring substrate, and the semiconductor chip is housed into the cavity of the cap and is hermetically sealed.

4. A semiconductor module according to claim 1, wherein an area of the resin portion for sealing the passive component corresponds to a size of the semiconductor chip.

5. A semiconductor module according to claim 1, wherein a lower semiconductor chip is mounted to be flip-chip connected to the wiring layer on a side of the passive component in the center major portion of the wiring substrate, and the passive component and the lower semiconductor chip are sealed with the resin portion.

6. A semiconductor module manufacturing method, comprising the steps of:
connecting and mounting a passive component to a wiring layer in a center major portion of the wiring substrate;
forming selectively a resin portion, which seals the passive component, in an area except the wiring layer on a peripheral side of the wiring substrate; and
adhering a semiconductor chip onto the resin layer, and connecting and mounting the semiconductor chip onto the wiring layer exposed from the peripheral side of the wiring substrate via a wire.

7. A semiconductor module manufacturing method according to claim 6, further comprising the step of:
forming a sealing resin to seal the semiconductor chip, the wire, and the wiring layer to which the wire is connected, after the step of mounting the semiconductor chip.

8. A semiconductor module manufacturing method according to claim 6, further comprising the step of:
providing a cap having a cavity after the step of mounting the semiconductor chip, and housing the semiconductor chip in the cavity of the cap to hermetically seal the semiconductor chip.

9. A semiconductor module manufacturing method according to claim 6, wherein the step of mounting the passive component on the wiring substrate includes the step of flip-chip connecting a lower semiconductor chip to the wiring layer on a side of the passive component, and
in the step of forming selectively the resin portion, the passive component and the lower semiconductor chip are sealed with the resin portion.

10. A semiconductor module manufacturing method according to claim 6, wherein, in the step of forming the resin portion, an area of the resin portion is formed to correspond to a size of the semiconductor chip.
